(19) United States
(12) Patent Application Publication
(10) Pub. No.: US 2017/0092842 A1
(43) Pub. Date: Mar. 30, 2017

(54) STRAINED VOLTAGE-CONTROLLED MAGNETIC MEMORY ELEMENTS AND DEVICES

(71) Applicants: THE REGENTS OF THE UNIVERSITY OF CALIFORNIA, Oakland, CA (US); CALIFORNIA STATE UNIVERSITY, NORTHRIDGE, Northridge, CA (US)

(72) Inventors: Pedram Khalili Amiri, Los Angeles, CA (US); Qi Hu, Los Alamitos, CA (US); Kang L. Wang, Santa Monica, CA (US); Nicholas Kioussis, Northridge, CA (US); Phuong-Vu Ong, Northridge, CA (US)

(73) Assignees: THE REGENTS OF THE UNIVERSITY OF CALIFORNIA, Oakland, CA (US); CALIFORNIA STATE UNIVERSITY, NORTHRIDGE, Northridge, CA (US)

(21) Appl. No.: 15/250,457

(22) Filed: Aug. 29, 2016

Related U.S. Application Data
(60) Provisional application No. 62/214,264, filed on Sep. 4, 2015.

(51) Int. Cl. H01L 43/02; H01L 43/10; H01L 27/22; H01L 43/08

(52) U.S. Cl. CPC H01L 43/02; H01L 43/08; H01L 43/10; H01L 27/224

(57) ABSTRACT

A magnetic memory bit structure using voltage-controlled magnetic anisotropy (VCMA) for switching the state of at least one magnetic free layer (FL) is configured for inducing strain to achieve very large VCMA coefficients, toward reducing the electric field potential and/or voltage required for switching the state of the magnetic free layer (FL). The disclosed apparatus and method increases voltage-controlled magnetic anisotropy (VCMA) efficiency, which is the change of interfacial magnetic anisotropy energy per unit electric field, thus exploiting strain engineering in designing next generation MeRAM devices which operate more efficiently with lower switching thresholds.

### CROSS-REFERENCE TO RELATED APPLICATIONS

This application claims priority to, and the benefit of, U.S. provisional patent application Ser. No. 62/214,264 filed on Sep. 4, 2015, incorporated herein by reference in its entirety.

### STATEMENT REGARDING FEDERALLY SPONSORED RESEARCH OR DEVELOPMENT

This invention was made with Government support under 1160504, awarded by the National Science Foundation; and HR0011-10-C-0153, awarded by the U.S. Department of Defense, Defense Advanced Research Projects Agency. The Government has certain rights in the invention.

### INCORPORATION-BY-REFERENCE OF COMPUTER PROGRAM APPENDIX

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND

1. Technical Field

The technology of this disclosure pertains generally to magnetic memory, and more particularly to induced mechanical strain magnetic memory devices.

2. Background Discussion

Previous publications have disclosed a magnetic memory bit with perpendicular or in-plane magnetization utilizing the voltage-control of magnetic anisotropy (VCMA) effect.

Electric field (E-field) control of the magnetization vector through using the magnetoelectric effect has created intense interest in the field toward developing ultra-low power, highly-scalable, and non-volatile spin-based random access memory or MeRAM. The operating principles of MeRAM are based on voltage-controlled magnetic anisotropy (VCMA) of heavy-metal/ferromagnet/insulator (HM/FM/I) nano-junctions, where the non-magnetic HM contact electrode (i.e., Ta, Pd, Pt, Au) has strong spin-orbit coupling (SOC). In the linear regime, the VCMA is proportional to the E-field in the insulator, VCMA=βE_{I}=βEₑₓₜ/∈_{⊥}, where β is the VCMA coefficient, Eₑₓₜ is the external E-field, and ∈_{⊥} is the out-of-plane component of the relative dielectric constant tensor of the insulator. The challenge for achieving a switching energy per bit which is below that in complementary metal oxide semiconductor (CMOS) (i.e., approximately 1 fJ) and a write voltage below about 1 V requires large perpendicular magnetic anisotropy (PMA) and a VCMA coefficient higher than approximately 200 fJ/Vm.

The VCMA of HM/FM/I junctions depends on the HM cap, the particular FM material or its alloys utilized, and the junction exhibits a wide range of behavior ranging from linear to nonmonotonic V-shape or inverse-V-shape ( [symbol] ) E-field dependence with asymmetric β's. A linear VCMA was observed in Ta/Co₄₀Fe₄₀B₂₀/MgO and in Pd/FePd/MgO tunnel junctions with β of −33 and +600 fJ/Vm, respectively, where the convention of positive E-field corresponds to electron accumulation at the FM/I interface.

To date, however, a major bottleneck in optimizing the performance of MeRAM devices is the low voltage-controlled magnetic anisotropy (VCMA) efficiency, in which the change of interfacial magnetic anisotropy energy per unit electric field leads to a high switching energy and write voltage.

Accordingly, a need exists for advanced MeRAM techniques which overcome the performance bottlenecks with regard to VCMA switching efficiencies. The present disclosure overcomes those shortcomings and provides additional benefits for advanced MeRAM.

### BRIEF SUMMARY

Improvements are disclosed for non-volatile spin-based random access memory (MeRAM), such as using a magnetic memory bit (magnetoelectric tunnel junction, or MEJ). Additional engineering steps are described which allow for incorporating mechanical strain into the device. This technology enables a dramatic reduction (e.g., approximately a factor of 10) of the voltage required to switch magnetic memory devices by electric fields, from the current typical range of 1-2 V to about 100-200 mV. This can provide major advantages in terms of energy efficiency (approximately a 100 fold improvement), as well as capability to integrate such memory devices with existing CMOS logic circuits. This enables a whole array of new products which are not possible with the larger switching voltages.

Uses of the technology described herein include nonvolatile memory and data storage, including replacement of existing SRAM, DRAM, and NAND flash, as well as nonvolatile logic gates and circuits in microprocessors. Other applications may include custom memory or data processing chips such as content-addressable memory (CAM) circuits.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWING(S)

The technology described herein will be more fully understood by reference to the following drawings which are for illustrative purposes only:

FIG. 1 is a cross-section of a magnetoelectric tunnel junction for use in a magnetic memory bit according to an embodiment of the present disclosure.

FIG. 2 is a pictorial view of two magnetoelectric tunnel junctions and associated access devices within a portion of a magnetic memory device configured according to an embodiment of the present disclosure.

FIG. 3 is a cross-section of a magnetoelectric tunnel junction, with inverted MEJ trilayer core according to an embodiment of the present disclosure.

FIG. 4 is a cross-section of a magnetoelectric tunnel junction with MIM access device of a first area utilized according to an embodiment of the present disclosure.

FIG. 5 is a cross-section of a magnetoelectric tunnel junction with MIM access device of a second area utilized according to an embodiment of the present disclosure.

FIG. 6 is a cross-section of a magnetoelectric tunnel junction with PN access device of a first area utilized according to an embodiment of the present disclosure.

FIG. 7 is a cross-section of a magnetoelectric tunnel junction with PN access device of a second area utilized according to an embodiment of the present disclosure.

FIG. 8 is a cross-section of a magnetoelectric tunnel junction with MN Schottky access device of a first area utilized according to an embodiment of the present disclosure.

FIG. 9 is a cross-section of a magnetoelectric tunnel junction with MN Schottky access device of a second area utilized according to an embodiment of the present disclosure.

FIG. 10 is a pictorial view of a 2-bit portion of a magnetoelectric memory with each MEJ comprising a strain-engineered bit, according to an embodiment of the present disclosure.

FIG. 11A is a cross section of a ferromagnetic structure utilized according to an embodiment of the present disclosure.

FIG. 11B is a plot of strain dependence of zero-field magnetic anisotropy (MA) in the structure of FIG. 11A.

FIG. 12A through FIG. 12F are plots of magnetic anisotropy (MA) for demonstrating strained characteristics utilized according to an embodiment of the present disclosure.

### DETAILED DESCRIPTION

A magnetoelectric tunnel junction (MEJ) comprises a ferromagnetic fixed layer in which magnetic polarization direction is fixed, a ferromagnetic free layer (FL) that is magnetically anisotropic, and a dielectric or other tunnel barrier retained between the FL and fixed layer. Application of a sufficient voltage potential across the magnetoelectric junction, can be used to change the magnetic anisotropy of the ferromagnetic free layer. The disclosure describes utilizing strain within the MEJ structure, such that the relative position of atoms within at least one layer in the MEJ stack is different from their equilibrium separation in an unstrained film of similar thickness, or in the material in its bulk, unperturbed equilibrium state. Strain solely in the free layer (FL), in the seed layer (SL), tunnel barrier (TB) or at their interfaces will significantly affect the VCMA effect by affecting the shape, hybridization, and occupancy of atomic orbitals, which in turn affects the magnetic anisotropy and its voltage dependence.

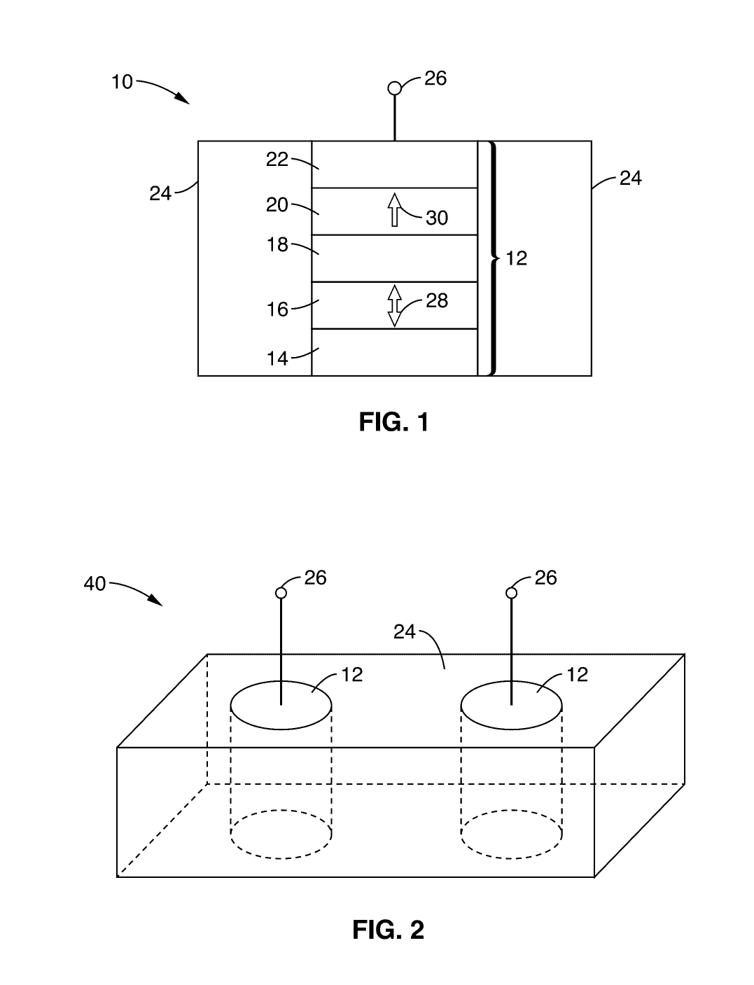

FIG. 1 illustrates one non-limiting embodiment 10 of the disclosed magnetic memory bit (magnetoelectric tunnel junction, or MEJ) 12 with in-plane or perpendicular magnetization. In one embodiment, the device comprises at least the following layers: a seed layer (SL) 14; a magnetic free layer (FL) 16; a tunnel barrier (TB) 18; a magnetic fixed layer 20; and a cap layer (CL) 22. The MEJ 12 is shown surrounded by dielectric material 24 for isolating MEJs on a substrate.

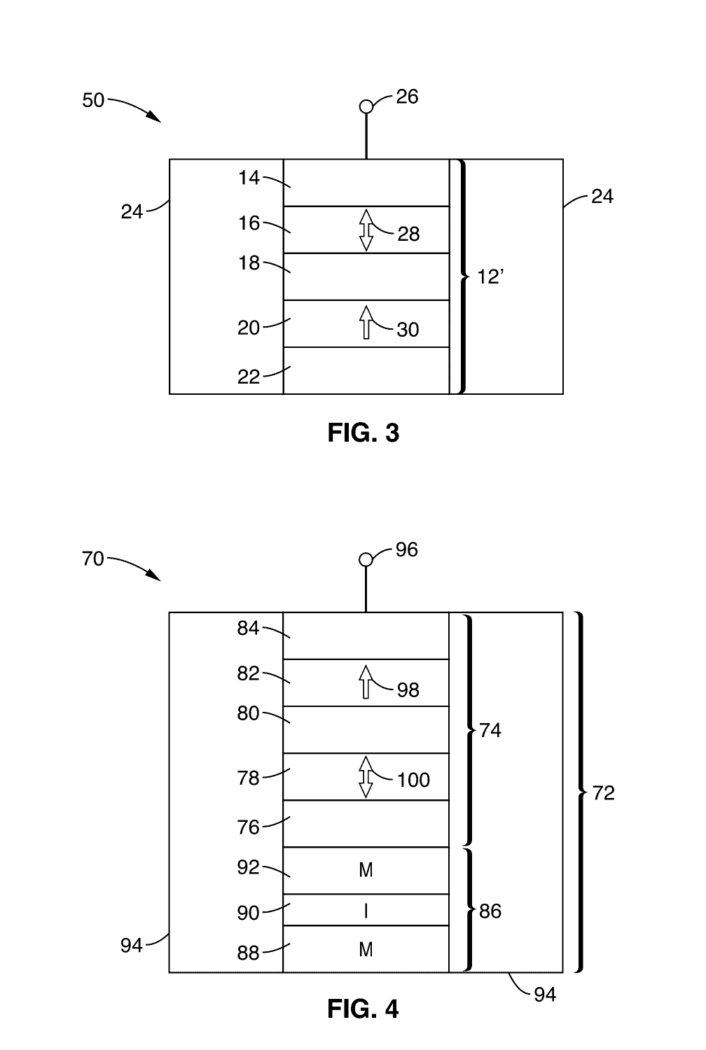

In the embodiment shown, the magnetization of the free layer 16 and the fixed layer 20 are pointing 28, 30 substantially parallel or anti-parallel with respect to each other, and may each be in-plane or perpendicular to the sample plane. A voltage (i.e., electric field) is applied across the memory bit using the cap layer 22 and seed layer 14, or using additional metal electrodes connected to them, such as cap electrode 26, to control the perpendicular magnetic anisotropy at the FL/TB interface, or at the FL/SL interface (or instead the FL/CL interface if the FL is in contact with the CL as in FIG. 3), or within the FL, or a combination of these. This effect is referred to as voltage-controlled magnetic anisotropy (VCMA), and can be utilized for switching the state of the free layer (FL).

In response to the applied voltage, the coercivity of the free layer is reduced, allowing for switching to the opposite magnetic state, either purely in response to the voltage pulse, or due to the combination of the voltage pulse and an additional influence, such as a current applied through the device resulting in spin transfer torque, or field like torque, or a current passed laterally through the SL resulting in a spin-orbit torque, or a magnetic field generated either by a current in an adjacent metallic wire, or by other means without limitation.

FIG. 2 illustrates an MEJ embodiment 40 in which the whole structure of the magnetic bits 12 are patterned into a circular or elliptical shape, with typical lateral dimensions smaller than 200 nm, and the field area in between the memory bits is isolated by one or more layers of dielectric material 24. A cap side electrode contact 26 is shown on a first side, while another electrode contact can be connected to the seed side, or a contact layer, strip or other structure utilized to make contact with both sides of MEJ 12.

In addition, the memory bit structure is strained, such that the relative position of atoms within at least one layer in the stack is different from their equilibrium separation in an unstrained film of similar thickness, or in the material in its bulk, unperturbed equilibrium state. Strain solely in the free layer (FL), in the seed layer (SL), tunnel barrier (TB) or at their interfaces will significantly affect the VCMA effect by affecting the shape, hybridization, and occupancy of atomic orbitals, which in turn affects the magnetic anisotropy and its voltage dependence. This has been verified by ab-initio electronic structure calculations. This configuration of the layer material can be integrated into the device to increase the magnitude of VCMA, hence resulting in a lower switching voltage and improved energy efficiency and reliability when the MEJ is used as a memory element (e.g., in MeRAM).

FIG. 3 illustrates an MEJ embodiment 50 showing the junction trilayer section 16, 18, 20 of MEJ 12′ in a reversed vertical order between the seed layer (SL) 14 and capping layer (CL) 22. It should be appreciated that although FIG. 1 and FIG. 2 describe a structure with a magnetic free layer (FL) 16 adjacent the seed layer (SL) 14, this order may be reversed with the fixed layer 20 adjacent the seed layer (SL) 14, without otherwise affecting the present claims, embodiments, or operation of the device. In addition, it should be noted that each described layer may in itself comprise a composite of multiple layers, insofar as the composite of layer performs the function of the layer as designated, such as free layer, fixed layer, and so forth. For example, each of the SL or CL may themselves consist of multiple layers of metallic films or may even include thin oxide films. Furthermore, the MEJ may be incorporated into a device which includes other layers and elements, alternatively other layers and elements may be combined into the MEJ.

FIG. 4 illustrates an embodiment 70 of an MEJ 74 integrated together with an access device, exemplified herein as a metal-insulator-metal junction 86, isolated by a dielectric 94 within a memory cell 72. The MEJ is shown with a seed layer (SL) 76; a magnetic free layer (FL) 78; a tunnel barrier (TB) 80; a magnetic fixed layer 82; and a cap layer (CL) 84. Magnetization 98, 100 is shown, respectively, for fixed layer 82 and free layer (FL) 78 which may point substantially parallel or anti-parallel with respect to each other. A contact 96 is depicted, by way of example and not limitation, on a first end of the memory cell 72. Access device 86 is shown with a first metal layer 88, an insulator 90, and a second metal layer 92.

Although the access device is exemplified above as MIM, it should be appreciated that the access device can comprise any device technology or combination as would be known to one of ordinary skill in the art. By way of example and not limitation, the access device may be selected from the group of access device types consisting of diodes, pn-junctions, Schottky diodes, metal-insulator-metal junctions, tunnel diodes, transistors, thin-film transistors, alternative circuits for providing memory bit access, and combinations thereof. The combination of MEJ 74, access device 86, and isolation 94, form a memory unit comprising a magnetic bit of information and its access device, to be integrated into a memory array.

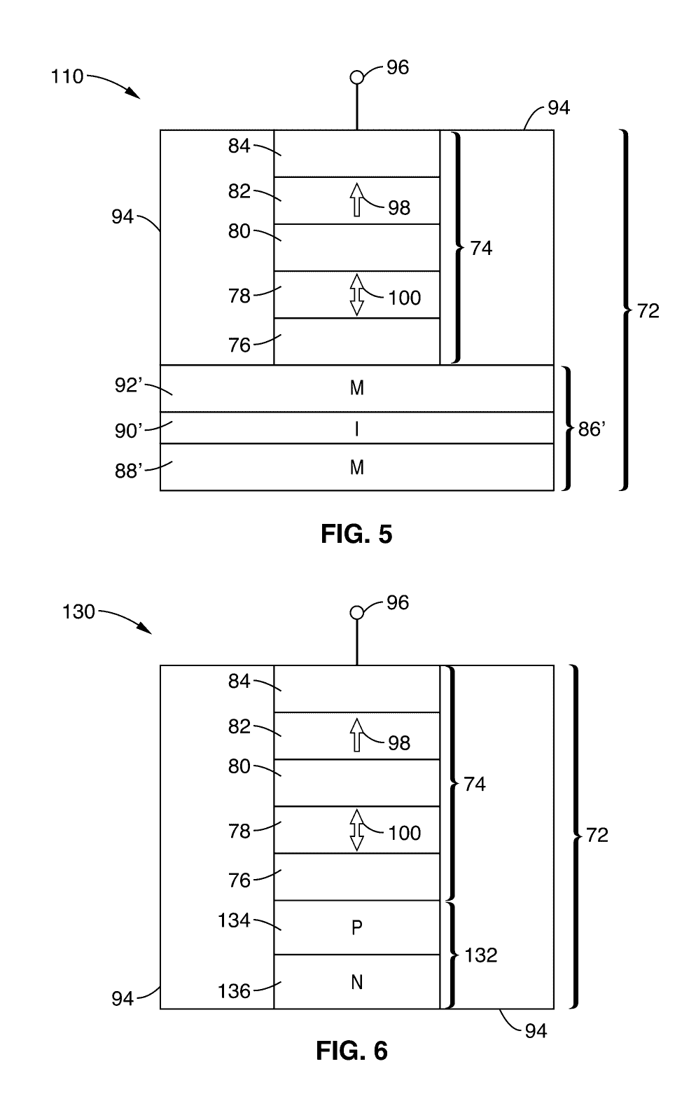

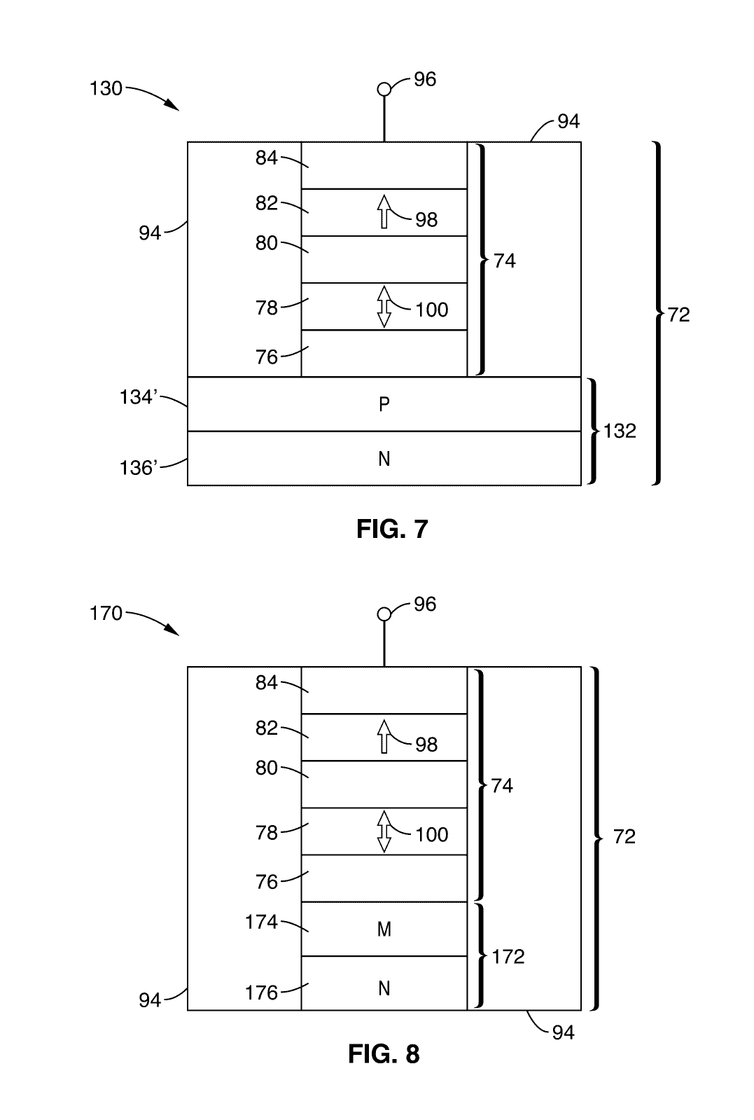

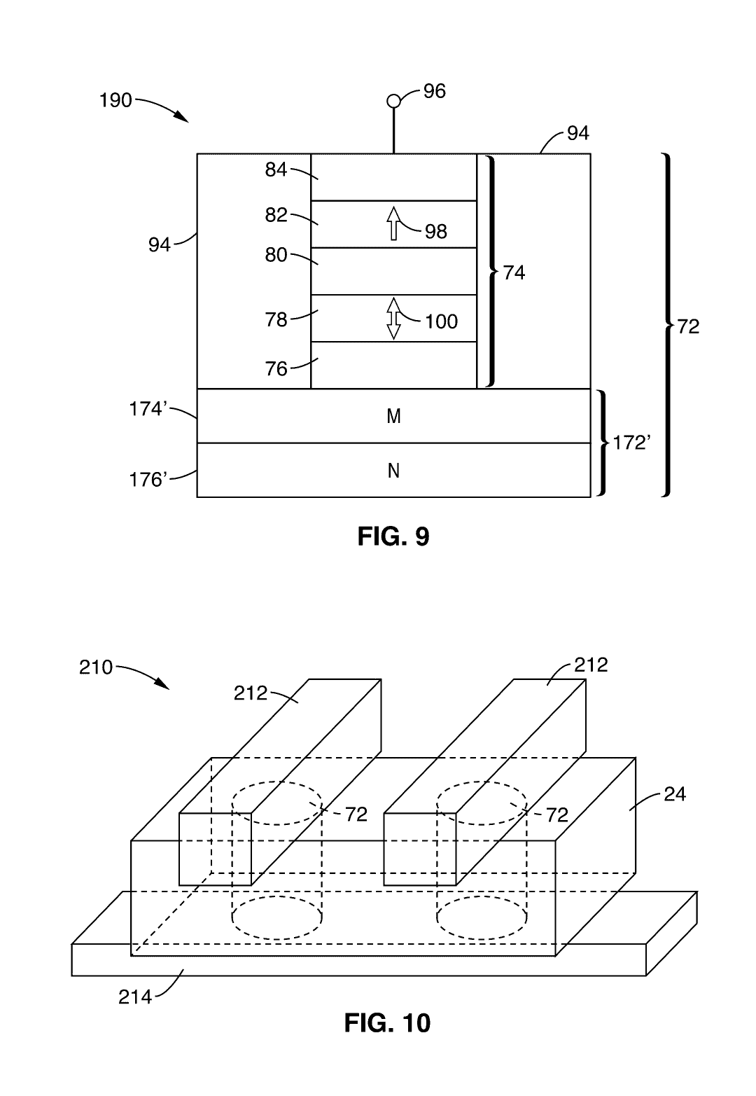

FIG. 5 through FIG. 9 illustrate, by way of example and not limitation, some additional embodiments of these MEJ memory cells. In FIG. 5 an example memory cell embodiment 110 is seen with MEJ 74 and having the access device 86′ as layers or spanning a larger area than MEJ 74. In this example the access device 86′ is also an MIM with a first metal layer 88′, an insulator 90′, and a second metal layer 92′. In FIG. 6 an example memory cell embodiment 130 is seen with MEJ 74 and having the access device 132 as a p-n junction diode with a layer of p-doped material 134, and a layer of n-doped material 136. In FIG. 7 an example memory cell embodiment 150 is seen with the same p-n junction diode as in FIG. 6, but now spans a different planar area (e.g., depicted as wider by way of example and not limitation) than the MJE 74, with a layer of p-doped material 134′, and a layer of n-doped material 136′. In FIG. 8 an example memory cell embodiment 170 is seen with MEJ 74 over an access device 172 comprising a metal-semiconductor Schottky diode exemplified with a metal layer 174 over a semiconductor material layer 176 depicted for instance as n-type semiconductor. In FIG. 9 an example memory cell embodiment 190 is seen with MEJ 74 over an access device 172′ comprising a metal-semiconductor Schottky diode spanning a different area than the MEJ layers, showing metal layer 174′ over a semiconductor material layer 176′ (e.g., n-type semiconductor).

In each of the above embodiments, the access device serves to limit leakage paths when integrated into an array, and improves read characteristics, and selection of the device. In a typical memory array implementation, such memory units would be additionally connected to metal lines (bit lines and source lines or word lines), such as into a crossbar memory array.

In the following section, methods and structures are disclosed to introduce strain into the aforementioned memory bits to enhance the VCMA effect to improve write characteristics.

Method 1: In one embodiment, strain can be induced into the free layer (FL) from either the seed layer or cap layer, depending if the material stack is inverted as described earlier. It will be noted that typically a metal seed layer is deposited (e.g., Cr or Mo but not limited thereto) or a composite seed layer (e.g., Cr/Ta or Mo/Ta, but not limited thereto) is deposited first before the following layers. The crystallinity of the seed layer can be improved by in-situ annealing at elevated temperatures. By configuring the MEJ design with this different lattice constant of the seed layer than in the FL, the lattice mis-match introduces strain into the FL. The technology described herein further encompasses all seed layers used to induce strain in such manner, including but not limited to Cr, Mo, Hf, and Au.

It should be appreciated that the deposition of these layers may be immediately followed by deposition of the FL, or additional steps may be interjected to improve the performance, e.g., annealing of the SL (or part of the SL deposited at that time) at a temperature of typically higher than 200° C., to improve its crystallinity, and/or deposition of an additional layer of other metal such as Ta before the FL to improve the crystallinity of the FL and enhance spin polarization (hence tunneling magnetoresistance).

It should also be appreciated that inducing strain may not be the sole role of the introduced layer in the stack. For example, this introduced layer can be configured to simultaneously serve other purposes, such as for modifying the conductivity of the electrode stack, or serving as part of a conductive path when current-induced write mechanisms are to be used in conjunction with a voltage-induced effect.

In various embodiments, the technology described herein encompasses SL/FL/TB material stacks of Cr/CoFeB/MgO, Au/CoFeB/MgO, Mo/CoFeB/MgO, Cr/Ta/CoFeB/MgO, Au/Ta/CoFeB/MgO, and Mo/Ta/CoFeB/MgO, but embodiments are not limited to these material stacks. In addition, in the case of the inverted structures, such as represented in FIG. 3, the CL which is on top of the FL may be engineered to have strain in the same way as the SL herein.

Method 2: In one embodiment, strain can be controlled at the FL/TB interface by tuning the composition of the FL alloy. A FL typically consists of a single element material including but not limited to Fe or Co or Ni or Mn, or alloys including but not limited to FeCo or FeCoB or FeGaB or FePt or FePd. A tunnel barrier (TB) typically consists of high spin-filtering materials, including but not limited to MgO or Al₂O₃. To obtain high TMR ratio in a memory bit, the FL typically requires a bcc crystal structure and (001) plane in contact with (001) plane of the TB. The in-plane orientation of the FL and TB crystal lattice is aligned, such that the mis-match between the two lattice constants is minimized. Any non-zero lattice mis-match at the FL/TB interface will induce strain at this interface. In one embodiment, in the case of CoxFe1-x or (CoxFe1-x)B, a wide range of x ranging from 0 to 90% can induce strain at the CoFe/MgO or CoFeB/MgO interface, while maintaining the bcc crystal structure of the FeCo or FeCoB alloy and its (001) crystal plane with MgO, and hence maintaining high TMR ratio. Regarding the body-centered cubic (bcc) structure, it should be appreciated that in general strained FeCo or FeCoB will have body-centered tetragonal (bct) structure, not bcc.

In at least one embodiment, the strain can be further enhanced by high temperature thermal annealing of the total film stacks, typically at temperatures ranging from 200° C. to 400° C. The strain at the FL/TB interface is a monotonic function of the FL alloy composition. In one embodiment, the strain at the FL/TB interface can therefore be tuned by controlling the composition of the FL alloy. It is noted that in the case of a composite FL which consists of multiple layers of materials, the aforementioned FL refers to the single layer in contact with the TB. Similarly, in the case of a composite TB which consists of multiple layers of materials, the aforementioned TB refers to the single layer that is in contact with the FL.

Method 3: In one embodiment, strain can be induced by using high stress materials for the surrounding insulating materials, such as dielectric 24 seen in FIG. 1, in between memory bits shown in FIG. 2 (or similarly in the other figures). Typical insulating materials used for memory fabrication, such as SiO₂ or Al₂O₃, are of low stress. High stress materials, such as silicon nitride (Si₃N₄), can be used to induce strain into the memory bits. In one embodiment, all high-stress materials utilized to induce strain in such a manner into an MEJ bit, including but not limited to silicon nitride (Si₃N4) or diamond-like carbon (DLC) or a combination of such multiple layers. In addition, in one embodiment, the strain induced in the memory bit can be varied from isotropic to anisotropic by changing the shape of the memory bit. In one embodiment, uniaxial strain can be induced in memory bits of rectangular or elliptical shape, while biaxial strain will be induced in memory bits of square or circular shape.

The aforementioned voltage-controlled memory bits with strain engineered to enhance the VCMA effect may exhibit superior performance in terms of write power consumption and reliability compared to similar voltage-controlled memory bits without strain. These strained voltage-controlled memory bits in connection with diodes, transistors, or the like can be built in the same manner into large arrays for memory chip applications.

For illustration, the following three scenarios are provided as examples of the use of such strain-engineered memory bits for data retention. These are provided as examples only and the use of such strain-engineered devices described herein is by no means limited to these particular scenarios:

FIG. 10 illustrates Example 1, embodiment 210, of a magnetoelectric memory with each MEJ 72 comprising a strain-engineered bit. In this memory structure, the strained MEJ can be integrated with an access device (not shown), including but not limited to those shown in FIG. 4 through FIG. 9. Each bit is shown surrounded by a dielectric 24. The MEJ cells are integrated into a memory array by connecting top and bottom metal lines 212, 214 to individual memory units 72. For the sake of simplicity of illustration, only two adjacent memory units are depicted, whereas the memory array may span any desired geometry, layout rules, and number of cells, without limitation.

Application of a pulse voltage, timed to correspond to one half of the precession cycle of the free layer, or an odd multiple thereof, or a multitude of such timed pulses, can then be utilized to reverse the orientation of the bit. Typical duration of such a pulse would be from approximately 20 ps up to few nanoseconds. The selection of the particular bit to be written may be provided by the application of appropriate voltages to each metal line in the array, in a sequence which is well known in the art.

Example 2 is a spin torque memory embodiment with strain-engineered bits. The strained MEJ can be integrated with an access device including but not limited to those shown in FIG. 4 through FIG. 9. The increased VCMA caused by the strain can be used to reduce the current required for spin-torque-induced switching when a current is applied through the memory unit, given that the device resistance would result in a voltage being generated across it in this scenario, resulting in a reduction of the perpendicular magnetic anisotropy. Given that the spin torque critical current for switching is proportional to this perpendicular magnetic anisotropy, it would be reduced due to VCMA in this scenario. Opposite currents would switch the FL of the MEJ in opposite directions in this scenario, providing a current-induced write assisted by the strain-enhanced VCMA.

Example 3 is a spin-orbit torque memory embodiment with strain-engineered bits. The strained MEJ can be integrated with an access device including but not limited to those shown in FIG. 4 through FIG. 9, and integrated into a memory array by connecting top and bottom metal lines 212, 214 to individual memory units 72, such as shown in FIG. 10. Application of an in-plane current through the metal lines (such as the bottom metal line 214 in FIG. 10) can generate spin-orbit torque on the magnetization, for instance via the Rashba or spin Hall effects. In this case, the FL of the MEJ can be switched in opposite directions depending on the direction of current in the metal line 214. Selection among different strained MEJs can be provided by applying a voltage to the top metal lines 212 (FIG. 10), such that the VCMA results in a lower switching current for the memory units which are intended to be switched. This provides a current-induced write assisted by the strain-enhanced VCMA.

The following provides support for the functionality of strained voltage-controlled magnetic memory elements and devices according to the present teachings.

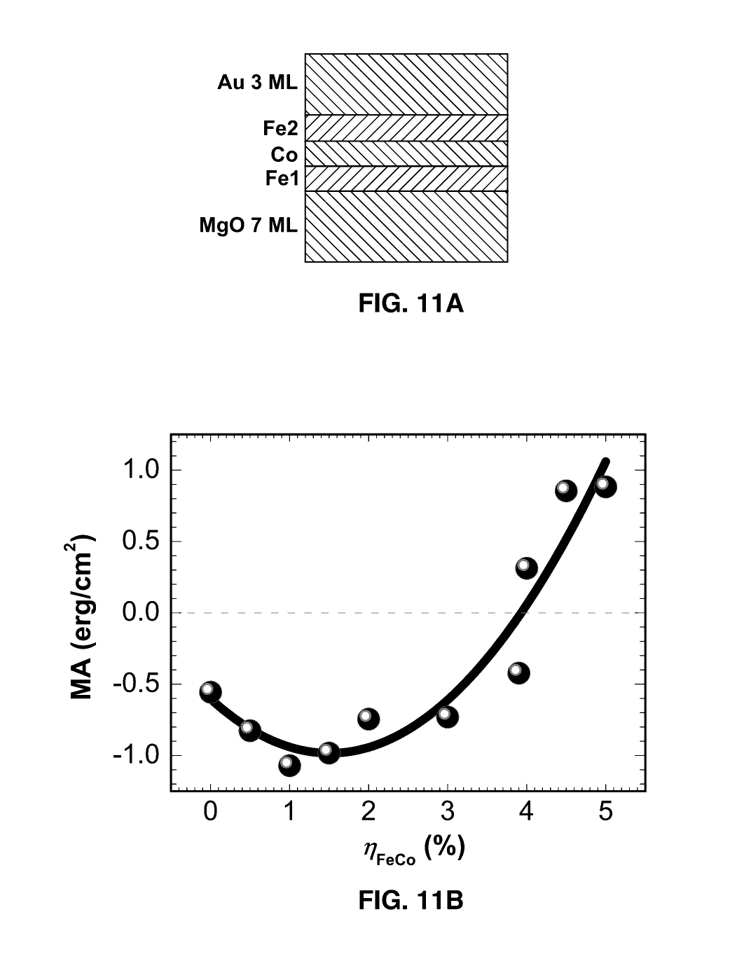

FIG. 11A denotes an example Au/FeCo/MgO junction structure utilized for testing aspects of MA strain dependence.

FIG. 11B depicts strain dependence of zero-field MA in the structure of FIG. 11A. Closed circles denote the ab initio results and the curve matches mathematical expectation. In the figure is seen the variation of the zero-field MA of the Au/FeCo/MgO junction with strain, ηFeCo. The iron atoms at the Fe/MgO and Fe/Au interfaces are denoted by Fe1 and Fe2, respectively. The system shows a nonlinear magnetoelastic (MEL) behavior with a spin-reorientation at approximately 4% strain, in contrast to that in Ta/FeCo/MgO where MA is linearly dependent on strain with a magnetization switching occurs at ˜approximately 2.5%. The above example of the effect of utilizing the HM cap on functional properties of a magnetic junction at nanoscale demonstrates the significant effects which can be achieved.

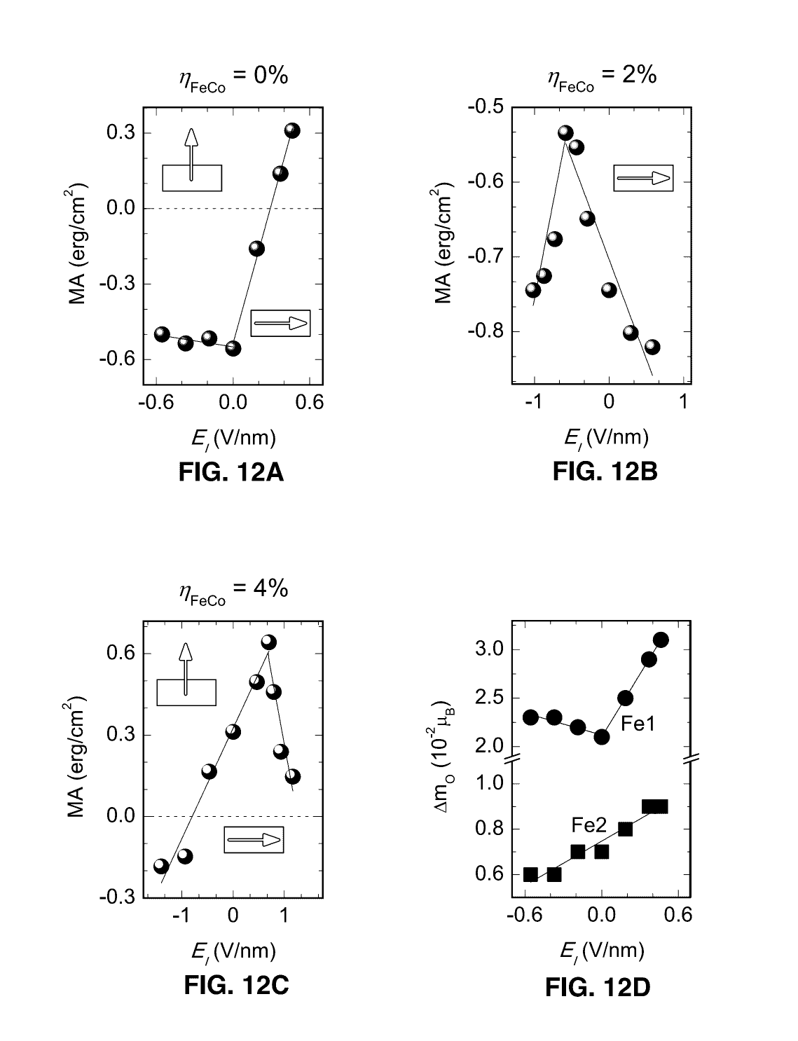

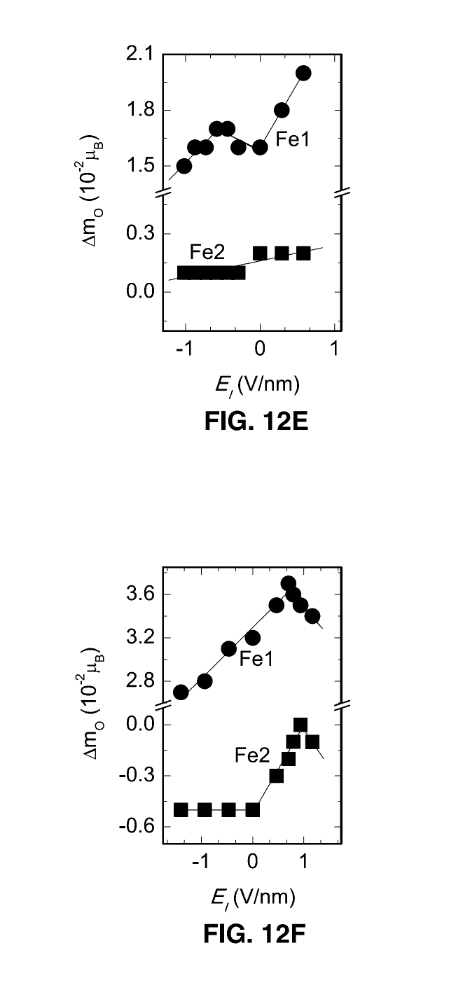

FIG. 12A through FIG. 12C depict magnetic anisotropy (MA) versus E-field in MgO for different strain values of for η_{FeCo}=0, 2 and 4%, respectively. The vertical (horizontal) arrows indicate perpendicular (in-plane) magnetization. The E-field in the insulator is inversely proportional to the strain-dependent out-of-plane component, ∈_{⊥}, of the dielectric tensor of the insulator. It was found that ∈_{⊥} increases exponentially with increasing compressive strain on the insulator (i.e., decreasing expansive strain on the FM). The calculated values of the relative ∈_{⊥}/∈₀ are 10.7, 17.0, and 27.0 for η_{FeCo}=4, 2, and 0%, respectively.

The results above demonstrate that epitaxial strain gives rise to a wide range of intriguing VCMA behavior where the MA changes from (i) asymmetric V-shape field behavior under 0% strain with β values of 1871 (−101) fJ/Vm for positive (negative) E-field; to (ii) asymmetric [symbol] -shape under 2% strain with β values of −246 (482) fJ/Vm for an E-field larger (smaller) than the critical field E_{c}=−0.58 V/nm where the MA reaches its maximum; and to (iii) asymmetric [symbol] -shape under 4% strain with β values of −1061 (393) fJ/Vm for E) E_{c}=0.70 V/nm. It should be noted that the range of E_{I} is below the breakdown field of MgO (approximately 1 V/nm). In most tests E_{I} is found below 0.7 V/nm, which is the value of E_{c} at 4%. Therefore, experimentally the VCMA appears linear at 4%.

As far as we know these VCMA coefficient values are the highest reported to date and are in fact larger by one to two orders of magnitude compared to those reported in published VCMA proposals, except in cases where charged defects could play a role.

Perhaps more importantly, we predict an E-field-driven switching of the magnetic easy axis from in-plane to out-of-plane direction at 0.30 (−0.80) V/nm for η_{FeCo}=0 (4)%. These findings have two important implications for magnetoelectric spintronics. First, the predicted VCMA coefficient values are very close to or larger than the critical value of about 200 fJ/Vm required to achieve a switching bit energy below 1 fJ in the next-generation of MeRAMs. Secondly, the results reveal the feasibility of tailoring the VCMA behavior via strain engineering to achieve desired MeRAM devices.

FIG. 12D through FIG. 12F depict orbital moment difference, Δmₒ=mₒ^{[001]}−mₒ^{[100]}, of the Fe1 and Fe2 interfacial atoms versus E-field for the same strain values (e.g., for η_{FeCo}=0, 2 and 4%), thus showing differences between the out-of- and in-plane orbital moments. The E-field variation of Δmₒ for Co is much weaker and is not shown here. For single atomic species FMs with large exchange splitting the MA is related to the orbital magnetic moment anisotropy via the Bruno expression MA=ξΔmₒ/(4μ_{B}). However, it should be noted that for structures consisting of multiple atomic species (as in the case of trilayers) with strong hybridization it has been shown that the expression is not satisfied and needs to be modified. Overall the E-field dependence of Δmₒ for Fe1 and to a lesser degree of Fe2 correlates with that of the MA.

It should be appreciated that there are different approaches to calculation of MA in magnetic alloys. For example, one proposal is to calculate MA and its thermal variation, based on relativistic extension of the Korringa-Kohn-Rostoker multiple scattering theory within coherent potential approximation (CPA) and calculation of magnetic torque.

It has been shown that MA values calculated from supercell approaches within the PAW methodology with SOC are in good agreement with other full potential methods and CPA approach, and for Fe—Co alloys very well describe experimental data for tetragonally distorted thin films.

For Fe₁₋ₓCoₓ alloys with x of approximately 0.5, MA values calculated at the levels of local density approximation and GGA exhibit no significant difference. The calculated MA values converges within 10%.

From the description herein, it will be appreciated that that the present disclosure encompasses multiple embodiments which include, but are not limited to, the following:

1. A magnetic memory bit, comprising: (a) magnetoelectric tunnel junction (MEJ) comprising: a seed layer (SL), a cap layer (CL), and an MEJ trilayer disposed between said seed layer (SL) and said cap layer (CL); (b) wherein said MEJ trilayer comprises a magnetic free layer (FL), a magnetic fixed layer, and a tunnel barrier (TB) disposed between said magnetic free layer (FL) and said magnetic fixed layer; and (c) wherein strain is induced within at least one layer of said magnetoelectric tunnel junction (MEJ) which changes the magnitude of electric field potential or voltage required to switch magnetic state of said magnetic free layer (FL) using voltage-controlled magnetic anisotropy (VCMA).

2. The magnetic memory bit of any preceding embodiment, wherein said magnetic free layer (FL) is configured for switching its in-plane or perpendicular magnetization in response to application of said electric field potential or voltage.

3. The magnetic memory bit of any preceding embodiment, further comprising application of an additional force to influence switching of state of the free layer (FL), as selected from a group of forces consisting of: application of current applied through said MEJ apparatus, application of current through a conductor placed in contact with said MEJ apparatus resulting in a spin-orbit torque on the FL, and application of current through a conductor placed in proximity to said MEJ apparatus resulting in generation of a magnetic field local to said free layer (FL).

4. The magnetic memory bit of any preceding embodiment, further comprising an access device coupled to said magnetoelectric tunnel junction (MEJ).

5. The magnetic memory bit of any preceding embodiment, wherein said access device comprises material layers having a comparable area for each layer as within said magnetoelectric tunnel junction (MEJ).

6. The magnetic memory bit of any preceding embodiment, wherein material layers within said access device have a different area than layers within said magnetoelectric tunnel junction (MEJ).

7. The magnetic memory bit of any preceding embodiment, wherein said access device is selected from a group of access devices consisting of diodes, pn-junctions, Schottky diodes, metal-insulator-metal junctions, tunnel diodes, transistors, or thin-film transistors.

8. The magnetic memory bit of any preceding embodiment, wherein a combination of said magnetic memory bit and said access device comprise a memory unit that is a component of a memory array.

9. The magnetic memory bit of any preceding embodiment, wherein said magnetoelectric tunnel junction (MEJ) comprises a strain engineered structure.

10. The magnetic memory bit of any preceding embodiment, wherein said strain is induced into the magnetic free layer (FL) from said seed layer (SL) or said cap layer (CL).

11. The magnetic memory bit of any preceding embodiment, wherein strain is controlled at the magnetic free layer (FL) to tunneling barrier (TB) interface by tuning alloy composition of said magnetic free layer (FL).

12. The magnetic memory bit of any preceding embodiment, wherein strain is induced in response to utilizing high stress insulating materials surrounding each memory bit, and/or between adjacent memory bits.

13. The magnetic memory bit of any preceding embodiment, wherein said magnetic memory bit is a component within a magnetoelectric memory having strain-engineered bits.

14. The magnetic memory bit of any preceding embodiment, wherein said magnetic memory bit is a component within a spin torque memory with strain-engineered bits.

15. The magnetic memory bit of any preceding embodiment, wherein strain of said strain-engineered bits increases voltage-controlled magnetic anisotropy (VCMA) to reduce current levels required for spin-torque-induced switching in response to an applied current.

16. The magnetic memory bit of any preceding embodiment, wherein opposite currents switch the FL of said MEJ in opposite directions, providing a current-induced write assisted by strain-enhanced voltage-controlled magnetic anisotropy (VCMA).

17. The magnetic memory bit of any preceding embodiment, wherein said magnetic memory bit is a component of spin-orbit torque memory with strain-engineered bits.

18. The magnetic memory bit of any preceding embodiment, wherein the FL of said MEJ in said spin torque memory can be switched in opposite directions depending on current direction through a metal line generating spin-orbit torque via spin Hall or Rashba effects.

19. The magnetic memory bit of any preceding embodiment, wherein selection among different strained memory bits of said spin-orbit torque memory is provided by applying a voltage to a selected bit, such that voltage-controlled magnetic anisotropy (VCMA) results in a lower switching current for memory units which are intended to be switched.

20. A magnetic memory bit, comprising: (a) a magnetoelectric tunnel junction (MEJ) configured with at least two magnetic orientations which can be set and sensed within said magnetic memory bit; (b) a seed layer (SL), a cap layer (CL), and an MEJ trilayer disposed between said seed layer (SL) and said cap layer (CL) within said magnetoelectric tunnel junction (MEJ); (c) wherein said MEJ trilayer comprises: (c)(i) a magnetic free layer (FL); (c)(ii) a magnetic fixed layer; and (c)(iii) a tunnel barrier (TB) disposed between said magnetic free layer (FL) and said magnetic fixed layer; (d) wherein strain is induced within at least one layer of said MEJ trilayer, said seed layer (SL), or said cap layer (CL), causing changes to relative atomic positions from their equilibrium separation; (e) wherein application of an electric field potential or voltage across said MEJ between said cap layer and said seed layer controls perpendicular magnetic anisotropy of the magnetic free layer (FL) at its interface with an adjacent layer to provide voltage-controlled magnetic anisotropy (VCMA) for switching state of the free layer (FL); (f) wherein in response to said strain a lower magnitude of electric field potential or voltage is required across said MEJ to provide voltage-controlled magnetic anisotropy (VCMA) in switching state of the free layer (FL).

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A magnetic memory bit, comprising:
(a) magnetoelectric tunnel junction (MEJ) comprising: a seed layer (SL), a cap layer (CL), and an MEJ trilayer disposed between said seed layer (SL) and said cap layer (CL);
(b) wherein said MEJ trilayer comprises a magnetic free layer (FL), a magnetic fixed layer, and a tunnel barrier (TB) disposed between said magnetic free layer (FL) and said magnetic fixed layer; and
(c) wherein strain is induced within at least one layer of said magnetoelectric tunnel junction (MEJ) which changes the magnitude of electric field potential or voltage required to switch magnetic state of said magnetic free layer (FL) using voltage-controlled magnetic anisotropy (VCMA).

2. The magnetic memory bit as recited in claim 1, wherein said magnetic free layer (FL) is configured for switching its in-plane or perpendicular magnetization in response to application of said electric field potential or voltage.

3. The magnetic memory bit as recited in claim 1, further comprising application of an additional force to influence switching of state of the free layer (FL), as selected from a group of forces consisting of: application of current applied through said MEJ apparatus, application of current through a conductor placed in contact with said MEJ apparatus resulting in a spin-orbit torque on the FL, and application of current through a conductor placed in proximity to said MEJ apparatus resulting in generation of a magnetic field local to said free layer (FL).

4. The magnetic memory bit as recited in claim 1, further comprising an access device coupled to said magnetoelectric tunnel junction (MEJ).

5. The magnetic memory bit as recited in claim 4, wherein said access device comprises material layers having a comparable area for each layer as within said magnetoelectric tunnel junction (MEJ).

6. The magnetic memory bit as recited in claim 4, wherein material layers within said access device have a different area than layers within said magnetoelectric tunnel junction (MEJ).

7. The magnetic memory bit as recited in claim 4, wherein said access device is selected from a group of access devices consisting of diodes, pn-junctions, Schottky diodes, metal-insulator-metal junctions, tunnel diodes, transistors, or thin-film transistors.

8. The magnetic memory bit as recited in claim 4, wherein a combination of said magnetic memory bit and said access device comprise a memory unit that is a component of a memory array.

9. The magnetic memory bit as recited in claim 1, wherein said magnetoelectric tunnel junction (MEJ) comprises a strain engineered structure.

10. The magnetic memory bit as recited in claim 1, wherein said strain is induced into the magnetic free layer (FL) from said seed layer (SL) or said cap layer (CL).

11. The magnetic memory bit as recited in claim 1, wherein strain is controlled at the magnetic free layer (FL) to tunneling barrier (TB) interface by tuning alloy composition of said magnetic free layer (FL).

12. The magnetic memory bit as recited in claim 1, wherein strain is induced in response to utilizing high stress insulating materials surrounding each memory bit, and/or between adjacent memory bits.

13. The magnetic memory bit as recited in claim 1, wherein said magnetic memory bit is a component within a magnetoelectric memory having strain-engineered bits.

14. The magnetic memory bit as recited in claim 1, wherein said magnetic memory bit is a component within a spin torque memory with strain-engineered bits.

15. The magnetic memory bit as recited in claim 14, wherein strain of said strain-engineered bits increases voltage-controlled magnetic anisotropy (VCMA) to reduce current levels required for spin-torque-induced switching in response to an applied current.

16. The magnetic memory bit as recited in claim 15, wherein opposite currents switch the FL of said MEJ in opposite directions, providing a current-induced write assisted by strain-enhanced voltage-controlled magnetic anisotropy (VCMA).

17. The magnetic memory bit as recited in claim 1, wherein said magnetic memory bit is a component of spin-orbit torque memory with strain-engineered bits.

18. The magnetic memory bit as recited in claim 17, wherein the FL of said MEJ in said spin torque memory can be switched in opposite directions depending on current direction through a metal line generating spin-orbit torque via spin Hall or Rashba effects.

19. The magnetic memory bit as recited in claim 17, wherein selection among different strained memory bits of said spin-orbit torque memory is provided by applying a voltage to a selected bit, such that voltage-controlled magnetic anisotropy (VCMA) results in a lower switching current for memory units which are intended to be switched.

20. A magnetic memory bit, comprising:
(a) a magnetoelectric tunnel junction (MEJ) configured with at least two magnetic orientations which can be set and sensed within said magnetic memory bit;
(b) a seed layer (SL), a cap layer (CL), and an MEJ trilayer disposed between said seed layer (SL) and said cap layer (CL) within said magnetoelectric tunnel junction (MEJ):
(c) wherein said MEJ trilayer comprises:
(i) a magnetic free layer (FL);
(ii) a magnetic fixed layer; and
(iii) a tunnel barrier (TB) disposed between said magnetic free layer (FL) and said magnetic fixed layer;
(d) wherein strain is induced within at least one layer of said MEJ trilayer, said seed layer (SL), or said cap layer (CL), causing changes to relative atomic positions from their equilibrium separation;
(e) wherein application of an electric field potential or voltage across said MEJ between said cap layer and said seed layer controls perpendicular magnetic anisotropy of the magnetic free layer (FL) at its interface with an adjacent layer to provide voltage-controlled magnetic anisotropy (VCMA) for switching state of the free layer (FL);
(f) wherein in response to said strain a lower magnitude of electric field potential or voltage is required across said MEJ to provide voltage-controlled magnetic anisotropy (VCMA) in switching state of the free layer (FL).
